(19) United States
(12) Patent Application Publication
(10) Pub. No.: US 2015/0206935 A1
(43) Pub. Date: Jul. 23, 2015

(54) COMPOUND SEMICONDUCTOR DEVICE AND METHOD OF MANUFACTURING THE SAME

(71) Applicant: FUJITSU LIMITED, Kawasaki-shi (JP)

(72) Inventors: Norikazu NAKAMURA, Sagamihara (JP); Atsushi YAMADA, Isehara (JP); Shiro OZAKI, Yamato (JP); Kenji IMANISHI, Atsugi (JP)

(21) Appl. No.: 14/671,826

(22) Filed: Mar. 27, 2015

Related U.S. Application Data
(62) Division of application No. 13/545,163, filed on Jul. 10, 2012.

(30) Foreign Application Priority Data
Sep. 26, 2011 (JP) 2011-209796

(51) Int. Cl. H01L 29/06; H01L 21/02; H01L 29/66; H01L 29/778

(52) U.S. Cl. CPC H01L 29/0607; H01L 29/778; H01L 21/02115; H01L 21/02266; H01L 21/02381; H01L 21/02488; H01L 21/02513; H01L 21/0254; H01L 29/66462

(57) ABSTRACT

An embodiment of a compound semiconductor device includes: a substrate; a compound semiconductor stacked structure formed over the substrate; and an amorphous insulating film formed between the substrate and the compound semiconductor stacked structure.

### CROSS-REFERENCE TO RELATED APPLICATIONS

This application is based upon and claims the benefit of priority of the prior Japanese Patent Application No. 2011-209796, filed on Sep. 26, 2011, the entire contents of which are incorporated herein by reference.

### FIELD

The embodiments discussed herein are related to a compound semiconductor device and a method of manufacturing the same.

### BACKGROUND

In recent years, there has been vigorous development of electronic devices (compound semiconductor devices) having a GaN layer and an AlGaN layer sequentially formed over a substrate, wherein the GaN layer is used as an electron channel layer. One of the compound semiconductor device is known as a GaN-based high electron mobility transistor (HEMT). The GaN-based HEMT makes a wise use of a high density two-dimensional gas (2DEG) which generates at the heterojunction interface between AlGaN and GaN.

The band gap of GaN is 3.4 eV, which is larger than the band gap of Si (1.1 eV) and the band gap of GaAs (1.4 eV). In other words, GaN has a large breakdown field strength. GaN also has a large saturation electron velocity. GaN is, therefore, a material of great promise for compound semiconductor devices operable under high voltage and capable of yielding large output. GaN is very promising also as a material for power source device directed to power saving.

However, it is very difficult to manufacture a GaN substrate with a good crystallinity. Major conventional solutions have been such as forming a GaN layer, AlGaN layer and so forth by hetero-epitaxial growth, over a Si substrate, sapphire substrate, SiC substrate or the like. In particular as for Si substrate, those having large diameter and high quality are readily available at low costs. Investigations into structures, having a GaN layer and an AlGaN layer formed over the Si substrate, have therefore been flourishing. Such investigations are exemplified by provision of a buffer layer such as AlN layer, aiming at buffering a large lattice mismatching of the GaN layer and the AlGaN layer, with respect to the Si substrate.

It has, however, been recognized that further improvement in the breakdown voltage would be difficult by the conventional techniques.

[Patent Literature 1] Japanese Laid-Open Patent Publication No. 2007-258230

[Patent Literature 2] Japanese Laid-Open Patent Publication No. 2010-245504

### SUMMARY

According to an aspect of the embodiments, a compound semiconductor device includes: a substrate; a compound semiconductor stacked structure formed over the substrate; and an amorphous insulating film formed between the substrate and the compound semiconductor stacked structure.

According to another aspect of the embodiments, a method of manufacturing a compound semiconductor device includes: forming an amorphous insulating film over a substrate; and forming a compound semiconductor stacked structure over the amorphous insulating film.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a drawing illustrating a result of SIMS;

FIG. 2 is a cross sectional view illustrating a structure of a compound semiconductor device according to a first embodiment;

FIGS. 3A to 3I are cross sectional views illustrating, in sequence, a method of manufacturing the compound semiconductor device according to the first embodiment;

FIG. 4 is a cross sectional view illustrating a structure of a compound semiconductor device according to a second embodiment;

FIG. 5 is a cross sectional view illustrating a structure of a compound semiconductor device according to a third embodiment;

FIG. 6 is a drawing illustrating a discrete package according to a fourth embodiment;

FIG. 7 is a wiring diagram illustrating a power factor correction (PFC) circuit according to a fifth embodiment;

FIG. 8 is a wiring diagram illustrating a power supply apparatus according to a sixth embodiment;

FIG. 9 is a wiring diagram illustrating a high-frequency amplifier according to a seventh embodiment;

FIGS. 10A and 10B are cross sectional views illustrating configurations of experimental samples; and

FIG. 11 is a drawing illustrating results of the experiment.

### DESCRIPTION OF EMBODIMENTS

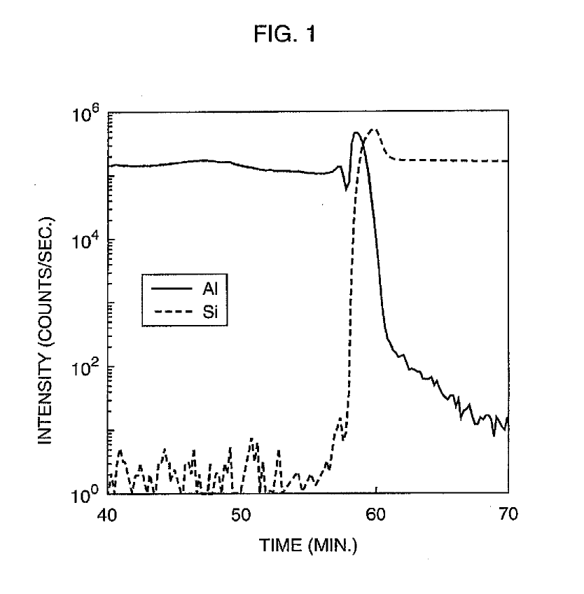

The present inventors have extensively investigated into the reasons why the difficulty in improving the breakdown voltage has arose in prior art. One of the investigations is SIMS (secondary ion mass spectrometry) directed to analyze the interface between the AlN buffer layer and the Si substrate. The result is illustrated in FIG. 1. It is found from FIG. 1, that Si contained in the Si substrate and Al contained in the buffer layer mutually diffuse. The thus-diffused atoms function as dopants for the both, and adversely affect the insulation performance. The phenomenon is supposed to make it difficult to further improve the breakdown voltage in prior arts. Degradation in the insulation performance also makes leakage current more likely to flow. For the reason, it is supposed to be difficult for prior arts to obtain a satisfactory level of reliability.

Embodiments will be detailed below, referring to the attached drawings.

### First Embodiment

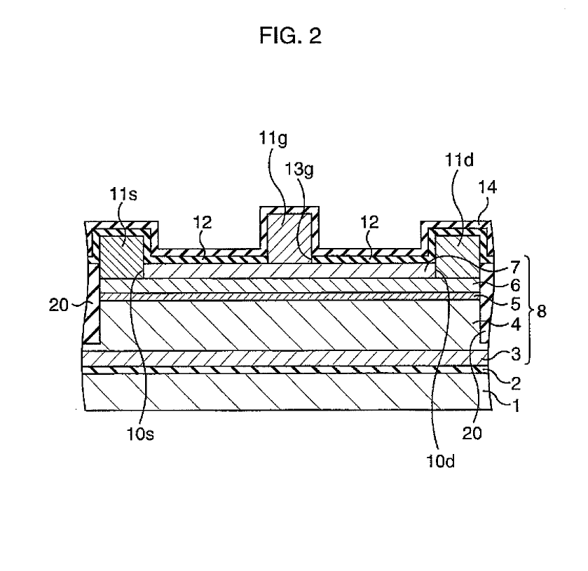

A first embodiment will be described. FIG. 2 is a cross sectional view illustrating a structure of a GaN-based HEMT (compound semiconductor device) according to the first embodiment.

In the first embodiment, as illustrated in FIG. 2, an amorphous insulating film 2 is formed over a substrate 1 such as a Si substrate. The amorphous insulating film 2 may be a film of amorphous C, amorphous SiN or amorphous SiC, wherein an amorphous carbon film having a density of 2.5 g/cm³ or larger is preferable. The high-density amorphous carbon film has an excellent insulation performance. Moreover, even if carbon diffuses from the high-density amorphous carbon film into the later-described buffer layer, the carbon may act to compensate nitrogen vacancy which is likely to occur in the process of growth, so that the insulation performance is expected to be restored.

A compound semiconductor stacked structure 8 is formed over the amorphous insulating film 2. The compound semiconductor stacked structure 8 includes a buffer layer 3, an electron channel layer 4, a spacer layer 5, an electron supply layer 6 and a cap layer 7. The buffer layer 3 may be an AlN layer having a thickness of approximately 100 nm, for example. The electron channel layer 4 may be an i-GaN layer having a thickness of approximately 3 μm, which is not intentionally doped with an impurity, for example. The spacer layer 5 may be an i-AlGaN layer having a thickness of approximately 5 nm, which is not intentionally doped with an impurity, for example. The electron supply layer 6 may be an n-type AlGaN layer having a thickness of approximately 30 nm, for example. The cap layer 7 may be an n-type GaN layer having a thickness of approximately 10 nm, for example. The electron supply layer 6 and the cap layer 7 may be doped with approximately 5×10¹⁸/cm³ of Si as an n-type impurity, for example.

An element isolation region 20 which defines an element region is formed in the compound semiconductor stacked structure 8. In the element region, openings 10s and 10d are formed in the cap layer 7. A source electrode 11s is formed in the opening 10s, and a drain electrode 11d is formed in the opening 10d. An insulating film 12 is formed so as to cover the source electrode 11s and the drain electrode 11d over the cap layer 7. An opening 13g is formed in the insulating film 12 at a position in planar view between the source electrode 11s and the drain electrode 11d, and a gate electrode 11g is formed in the opening 13g. An insulating film 14 is formed so as to cover the gate electrode 11g over the insulating film 12. While materials used for the insulating films 12 and 14 are not specifically limited, a Si nitride film may be used, for example.

In the GaN-based HEMT thus configured, the amorphous insulating film 2 exists between the substrate 1 and the buffer layer 3, and therefore atoms contained in the substrate 1 (Si, for example) and the atoms contained in the buffer layer 3 (Al, for example) are suppressed from mutually diffusing. Accordingly, the substrate 1 and the buffer layer 3 are suppressed from causing extrinsic generation of charge carriers, and from being degraded in the insulating performance. The breakdown voltage may be improved, and the leakage current may be suppressed, through the suppression of degradation in the insulating performance. Moreover, the amorphous insulating film 2 scarcely has grain boundary, which is supposed to be one reason for degradation in the breakdown voltage. Also from this point of view, the breakdown voltage is supposed to be improved.

A thickness of the amorphous insulating film 2 is not specifically limited. If the thickness of the amorphous insulating film 2 is 1 nm or smaller, however, a sufficient effect may not be obtain in some cases. It is, therefore, preferable for the amorphous insulating film 2 to have the thickness of 1 nm or larger. The thicker the amorphous insulating film 2 is, the better the insulating performance is. The thickness of the amorphous insulating film 2 exceeding 2 nm may, however, degrade the crystallinity of the compound semiconductor layer(s) contained in the compound semiconductor stacked structure 8. Accordingly, the thickness of the amorphous insulating film 2 is preferably 2 nm or smaller.

The amorphous insulating film 2 is not always necessarily to be amorphous over the entire portion thereof, but may contain micro-crystal or the like. The larger the ratio of crystal is, the more the grain boundary which serves as a leakage path increases. Accordingly, the ratio of amorphous portion is preferably 80% by volume or larger.

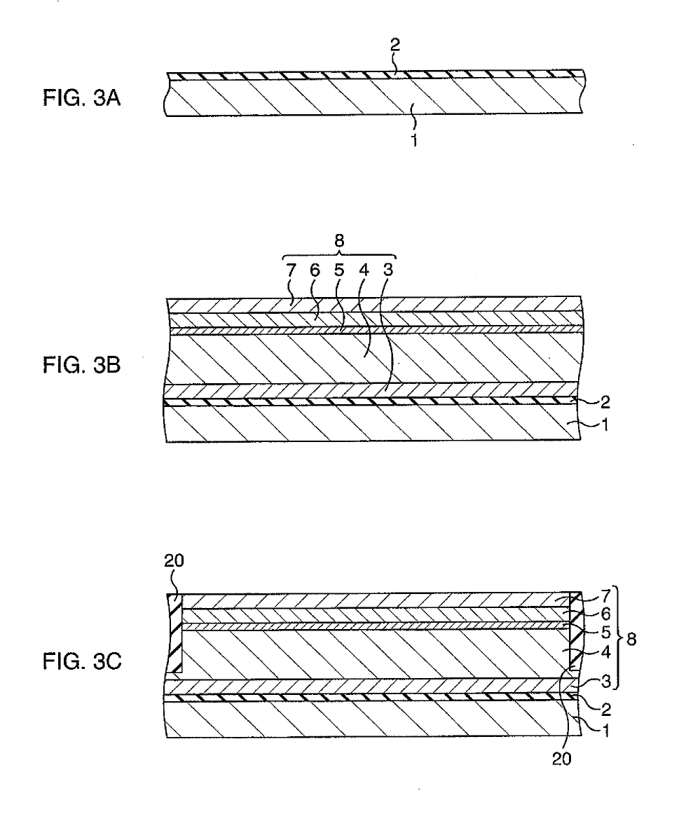

Next, a method of manufacturing the GaN-based HEMT (compound semiconductor device) according to the first embodiment will be explained. FIG. 3A to FIG. 3I are cross sectional views illustrating, in sequence, a method of manufacturing the GaN-based HEMT (compound semiconductor device) according to the first embodiment.

First, as illustrated in FIG. 3A, the amorphous insulating film 2 is formed over the substrate 1. While the method of forming the amorphous insulating film 2 is not specifically limited, an FCA (filtered cathodic arc) process is preferable. Because the FCA process readily forms an amorphous carbon film having a large density of 2.5 g/cm³ or more. For example, an amorphous carbon film having a large carbon-carbon bond ratio (sp³/sp² ratio), which is affective to the density, of 65% or more may readily be formed. According to the FCA process, higher density almost comparable to diamond may be achieved, as compared with a sputtering process and a chemical vapor deposition (CVD) process. In addition, the film growth does not need heating, so that the substrate 1 may be prevented from being damaged by heating in the process of film growth.

Next, as illustrated in FIG. 3B, the compound semiconductor stacked structure 8 is formed on the amorphous insulating film 2. In the process of forming the compound semiconductor stacked structure 8, the buffer layer 3, the electron channel layer 4, the spacer layer 5, the electron supply layer 6 and the cap layer 7 may be formed by metal organic vapor phase epitaxy (MOVPE), for example. In the process of forming the compound semiconductor layers, a mixed gas of trimethylaluminum (TMA) gas as an Al source, trimethylgallium (TMG) gas as a Ga source, and ammonia (NH₃) gas as a N source, may be used. In the process, on/off of supply and flow rates of trimethylaluminum gas and trimethylgallium gas are appropriately set, depending on compositions of the compound semiconductor layers to be grown. Flow rate of ammonia gas, which is common to all compound semiconductor layers, may be set to approximately 100 ccm to 10 LM. Growth pressure may be adjusted to approximately 50 Torr to 300 Torr, and growth temperature may be adjusted to approximately 1000° C. to 1200° C., for example. In the process of growing the n-type compound semiconductor layers, Si may be doped into the compound semiconductor layers by adding SiH₄ gas, which contains Si, to a mixed gas at a predetermined flow rate, for example. Dose of Si is adjusted to approximately 1×10¹⁸/cm³ to 1×10²⁰/cm³, and to 5×10¹⁸/cm³ or around, for example.

Next, as illustrated in FIG. 3C, the element isolation region 20 which defines the element region is formed in the compound semiconductor stacked structure 8. In the process of forming the element isolation region 20, for example, a photoresist pattern is formed over the compound semiconductor stacked structure 8 so as to selectively expose region where the element isolation region 20 is to be formed, and ion such as Ar ion is implanted through the photoresist pattern used as a mask. Alternatively, the compound semiconductor stacked structure 8 may be etched by dry etching using a chlorine-containing gas, through the photoresist pattern used as an etching mask.

Thereafter, as illustrated in FIG. 3D, the openings 10s and 10d are formed in the cap layer 7 in the element region. In the process of forming the openings 10s and 10d, for example, a photoresist pattern is formed over the compound semiconductor stacked structure 8 so as to expose regions where the openings 10s and 10d are to be formed, and the cap layer 7 is etched by dry etching using a chlorine-containing gas, through the photoresist pattern used as an etching mask.

Next, as illustrated in FIG. 3E, the source electrode 11s is formed in the opening 10s, and the drain electrode 11d is formed in the opening 10d. The source electrode 11s and the drain electrode 11d may be formed by a lift-off process, for example. More specifically, a photoresist pattern is formed so as to expose regions where the source electrode 11s and the drain electrode 11d are to be formed, a metal film is formed over the entire surface by an evaporation process while using the photoresist pattern as a growth mask, for example, and the photoresist pattern is then removed together with the portion of the metal film deposited thereon. In the process of forming the metal film, for example, a Ta film of approximately, 20 nm thick may be formed, and an Al film of approximately 200 nm thick may be then formed. The metal film is then annealed, for example, in a nitrogen atmosphere at 400° C. to 1000° C. (at 550° C., for example) to thereby ensure the ohmic characteristic.

Then as illustrated in FIG. 3F, the insulating film 12 is formed over the entire surface. The insulating film 12 is preferably formed by atomic layer deposition (ALD), plasma-assisted chemical vapor deposition (CVD), or sputtering.

Next, as illustrated in FIG. 3G, the opening 13g is formed in the insulating film 12 at a position in planar view between the source electrode 11s and the drain electrode 11d.

Next, as illustrated in FIG. 3H, the gate electrode 11g is formed in the opening 13g. The gate electrode 11g may be formed by a lift-off process, for example. More specifically, a photoresist pattern is formed so as to expose a region where the gate electrode 11g is to be formed, a metal film is formed over the entire surface by an evaporation process while using the photoresist pattern as a growth mask, for example, and the photoresist pattern is then removed together with the portion of the metal film deposited thereon. In the process of forming the metal film, for example, a Ni film of approximately 30 nm thick may be formed, and a Au film of approximately 400 nm thick may be then formed.

Thereafter, as illustrated in FIG. 3I, the insulating film 14 is formed over the insulating film 12 so as to cover the gate electrode 11g.

The GaN-based HEMT according to the first embodiment may be thus manufactured.

### Second Embodiment

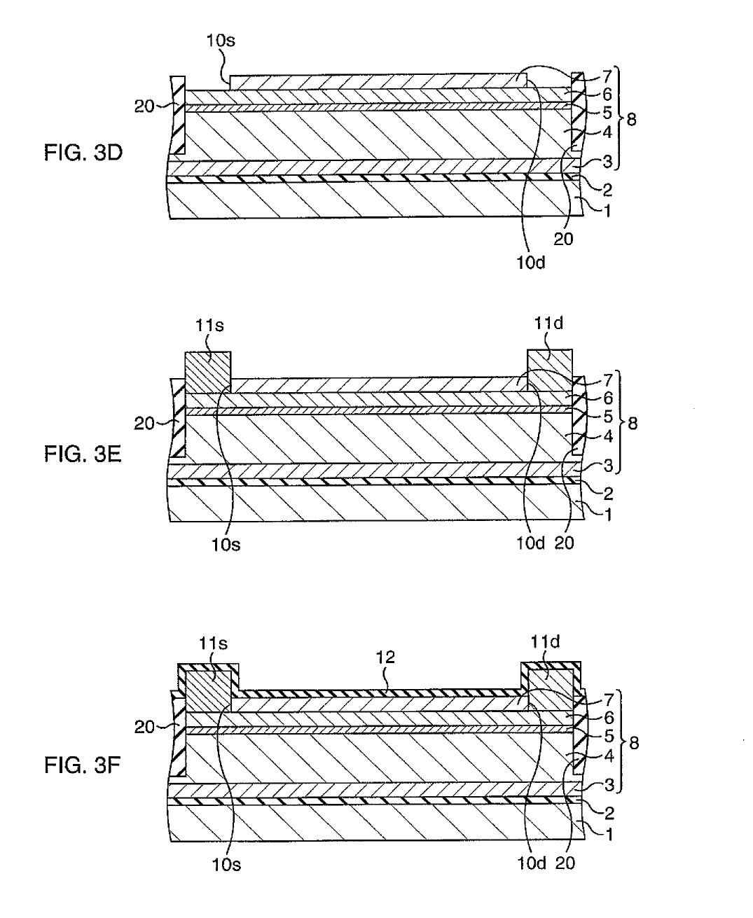

Next, a second embodiment will be explained. FIG. 4 is a cross sectional view illustrating a structure of a GaN-based HEMT (compound semiconductor device) according to the second embodiment.

In contrast to the first embodiment, having the gate electrode 11g brought into Schottky contact with the compound semiconductor stacked structure 8, the second embodiment adopts the insulating film 12 between the gate electrode 11g and the compound semiconductor stacked structure 8, so as to allow the insulating film 12 to function as a gate insulating film. In short, the opening 13g is not formed in the insulating film 12, and a MIS-type structure is adopted.

Also the second embodiment thus configured successfully achieves, similarly to the first embodiment, the effects of improving the breakdown voltage and suppressing the leakage current, with the presence of the amorphous insulating film 2.

A material for the insulating film 12 is not specifically limited, wherein the preferable examples include oxide, nitride or oxynitride of Si, Al, Hf, Zr, Ti, Ta and W. Aluminum oxide is particularly preferable. Thickness of the insulating film 12 may be 2 nm to 200 nm, and 10 nm or around, for example.

### Third Embodiment

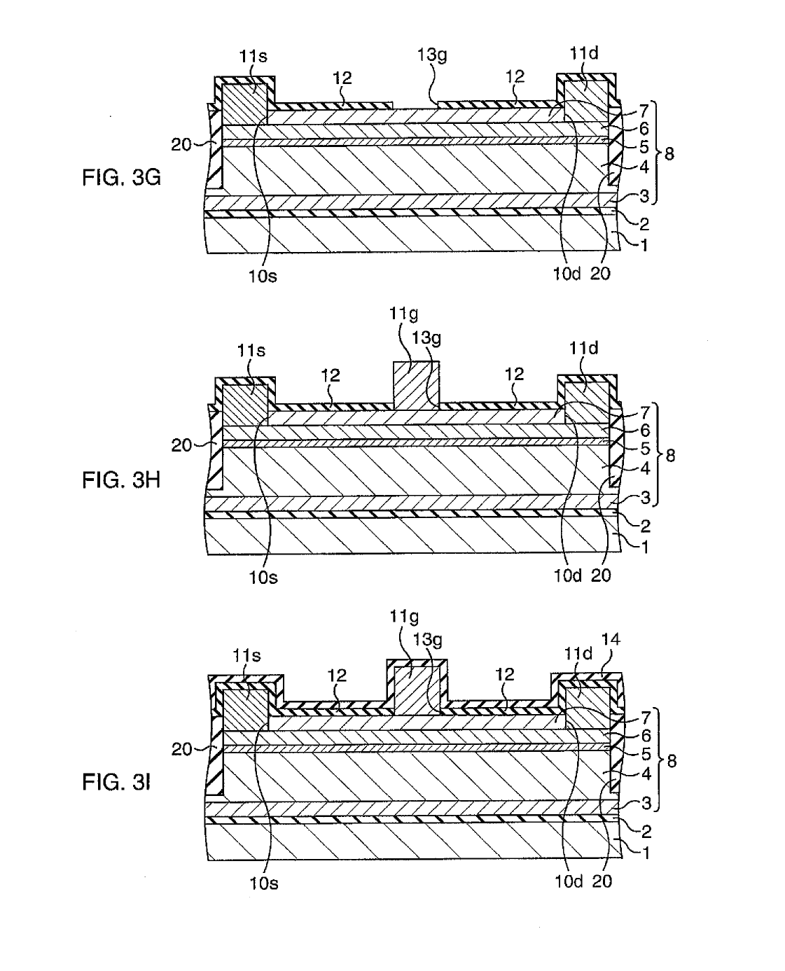

Next, a third embodiment will be explained. FIG. 5 is a cross sectional view illustrating a structure of a GaN-based HEMT (compound semiconductor device) of the third embodiment.

In contrast to the first embodiment, having the source electrode 11s and the drain electrode 11d formed in the openings 10s and 10d respectively, the openings 10s and 10d are not formed in the third embodiment. The source electrode 11s and the drain electrode 11d are formed on the cap layer 7.

Also the third embodiment thus configured successfully achieves, similarly to the first embodiment, the effects of improving the breakdown voltage and suppressing the leakage current, with the presence of the amorphous insulating film 2.

### Fourth Embodiment

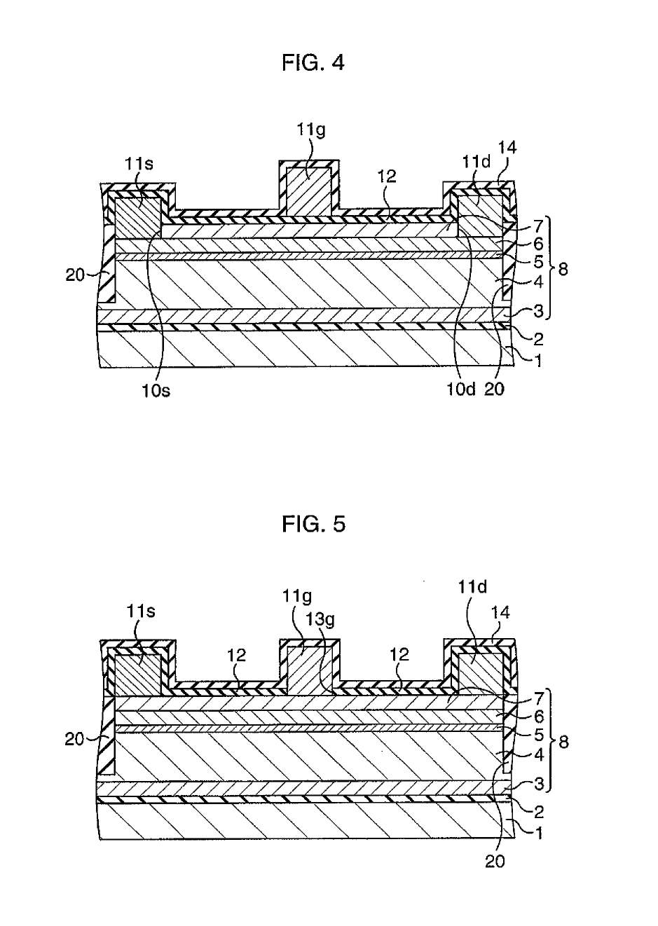

A fourth embodiment relates to a discrete package of a compound semiconductor device which includes a GaN-based HEMT. FIG. 6 is a drawing illustrating the discrete package according to the fourth embodiment.

In the fourth embodiment, as illustrated in FIG. 6, a back surface of a HEMT chip 210 of the compound semiconductor device according to any one of the first to third embodiments is fixed on a land (die pad) 233, using a die attaching agent 234 such as solder. One end of a wire 235d such as an Al wire is bonded to a drain pad 226d, to which the drain electrode 11d is connected, and the other end of the wire 235d is bonded to a drain lead 232d integral with the land 233. One end of a wire 235s such as ab Al wire is bonded to a source pad 226s, to which the source electrode 11s is connected, and the other end of the wire 235s is bonded to a source lead 232s separated from the land 233. One end of a wire 235g such as an Al wire is bonded to a gate pad 226g, to which the gate electrode 11g is connected, and the other end of the wire 235g is bonded to a gate lead 232g separated from the land 233. The land 233, the HEMT chip 210 and so forth are packaged with a molding resin 231, so as to project outwards a portion of the gate lead 232g, a portion of the drain lead 232d, and a portion of the source lead 232s.

The discrete package may be manufactured by the procedures below, for example. First, the HEMT chip 210 is bonded to the land 233 of a lead frame, using a die attaching agent 234 such as solder. Next, with the wires 235g, 235d and 235s, the gate pad 226g is connected to the gate lead 232g of the lead frame, the drain pad 226d is connected to the drain lead 232d of the lead frame, and the source pad 226s is connected to the source lead 232s of the lead frame, respectively, by wire bonding. The molding with the molding resin 231 is conducted by a transfer molding process. The lead frame is then cut away.

### Fifth Embodiment

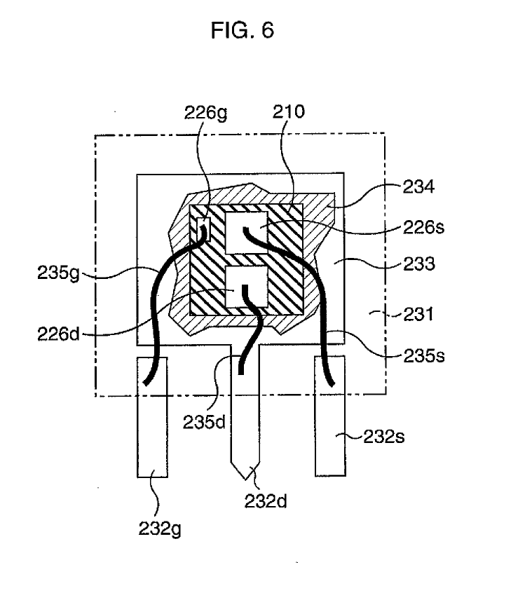

Next, a fifth embodiment will be explained. The fifth embodiment relates to a PFC (power factor correction) circuit equipped with a compound semiconductor device which includes a GaN-based HEMT. FIG. 7 is a wiring diagram illustrating the PFC circuit according to the fifth embodiment.

The PFC circuit 250 has a switching element (transistor) 251, a diode 252, a choke coil 253, capacitors 254 and 255, a diode bridge 256, and an AC power source (AC) 257. The drain electrode of the switching element 251, the anode terminal of the diode 252, and one terminal of the choke coil 253 are connected with each other. The source electrode of the switching element 251, one terminal of the capacitor 254, and one terminal of the capacitor 255 are connected with each other. The other terminal of the capacitor 254 and the other terminal of the choke coil 253 are connected with each other. The other terminal of the capacitor 255 and the cathode terminal of the diode 252 are connected with each other. A gate driver is connected to the gate electrode of the switching element 251. The AC 257 is connected between both terminals of the capacitor 254 via the diode bridge 256. A DC power source (DC) is connected between both terminals of the capacitor 255. In the embodiment, the compound semiconductor device according to any one of the first to third embodiments is used as the switching element 251.

In the process of manufacturing the PFC circuit 250, for example, the switching element 251 is connected to the diode 252, the choke coil 253 and so forth with solder, for example.

### Sixth Embodiment

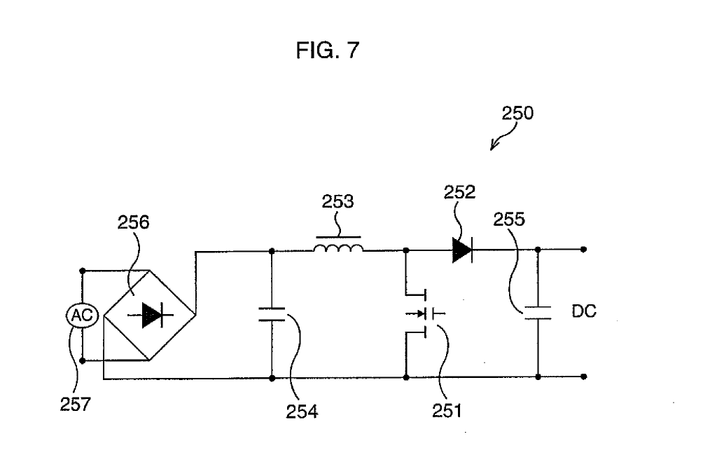

Next, a sixth embodiment will be explained. The sixth embodiment relates to a power supply apparatus equipped with a compound semiconductor device which includes a GaN-based HEMT. FIG. 8 is a wiring diagram illustrating the power supply apparatus according to the sixth embodiment.

The power supply apparatus includes a high-voltage, primary-side circuit 261, a low-voltage, secondary-side circuit 262, and a transformer 263 arranged between the primary-side circuit 261 and the secondary-side circuit 262.

The primary-side circuit 261 includes the PFC circuit 250 according to the fifth embodiment, and an inverter circuit, which may be a full-bridge inverter circuit 260, for example, connected between both terminals of the capacitor 255 in the PFC circuit 250. The full-bridge inverter circuit 260 includes a plurality of (four, in the embodiment) switching elements 264a, 264b, 264c and 264d.

The secondary-side circuit 262 includes a plurality of (three, in the embodiment) switching elements 265a, 265b and 265c.

In the embodiment, the compound semiconductor device according to any one of first to third embodiments is used for the switching element 251 of the PFC circuit 250, and for the switching elements 264a, 264b, 264c and 264d of the full-bridge inverter circuit 260. The PFC circuit 250 and the full-bridge inverter circuit 260 are components of the primary-side circuit 261. On the other hand, a silicon-based general MIS-FET (field effect transistor) is used for the switching elements 265a, 265b and 265c of the secondary-side circuit 262.

### Seventh Embodiment

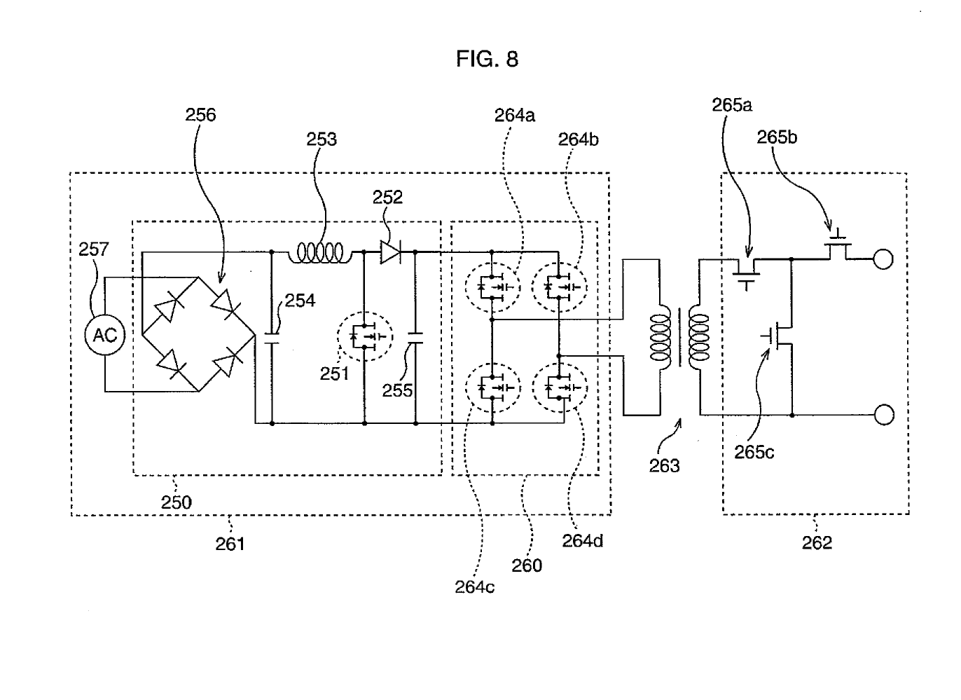

Next, a seventh embodiment will be explained. The seventh embodiment relates to a high-frequency amplifier equipped with the compound semiconductor device which includes a GaN-based HEMT. FIG. 9 is a wiring diagram illustrating the high-frequency amplifier according to the seventh embodiment.

The high-frequency amplifier includes a digital predistortion circuit 271, mixers 272a and 272b, and a power amplifier 273.

The digital predistortion circuit 271 compensates non-linear distortion in input signals. The mixer 272a mixes the input signal having the non-linear distortion already compensated, with an AC signal. The power amplifier 273 includes the compound semiconductor device according to any one of the first to third embodiments, and amplifies the input signal mixed with the AC signal. In the illustrated example of the embodiment, the signal on the output side may be mixed, upon switching, with an AC signal by the mixer 272b, and may be sent back to the digital predistortion circuit 271.

Composition of the compound semiconductor layers used for the compound semiconductor stacked structure is not specifically limited, and GaN, AlN, InN and so forth may be used. Also mixed crystals of them may be used. For example, the buffer layer may be an AlGaN layer, or a stack of an AlN layer and an AlGaN layer.

In the embodiments, the substrate may be a silicon carbide (SiC) substrate, a sapphire substrate, a silicon substrate, a GaN substrate, a GaAs substrate or the like. The substrate may be any of electro-conductive, semi-insulating, and insulating ones.

Configurations of the gate electrode, the source electrode and the drain electrode are not limited to those in the above-described embodiments. For example, they may be configured by a single layer. The method of forming these electrodes is not limited to the lift-off process. The annealing after the formation of the source electrode and the drain electrode is omissible, so long the ohmic characteristic is obtainable. The gate electrode may be annealed.

The thickness and materials for composing the individual layers are not limited to those described in the embodiments.

Next, results of an experiment, conducted by the present inventors for the purpose of investigating into the effects of the amorphous insulating film, will be explained.

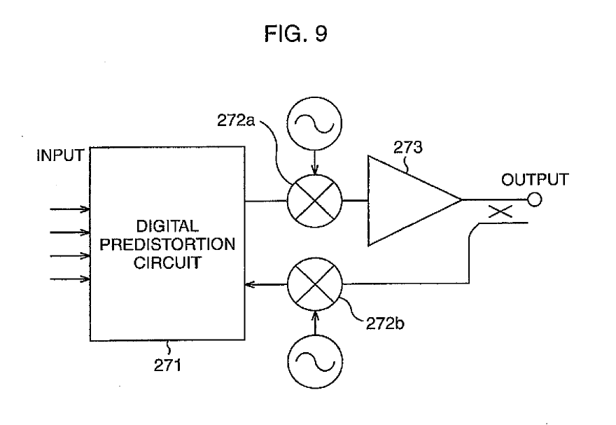

In the experiment, two types of samples 31 and 32 illustrated in FIGS. 10A and 10B were prepared. As for the sample 31, as illustrated in FIG. 10A, an AlN layer 23 of 200 nm thick was formed over the Si substrate 21. As for the sample 32, as illustrated in FIG. 10B, an amorphous carbon film of 2 nm thick was formed as the amorphous insulating film 22 over the Si substrate 21, and then the AlN layer 23 of 200 nm thick was formed over the amorphous insulating film 22. The AlN layer 23 was formed by a MOVPE process using TMA and NH₃ as the source gas at a growth temperature of 1000° C. and a growth pressure of 20 kPa. The amorphous insulating film 22 (amorphous carbon film) was formed by an FCA process using a graphite target as a source material at an arc current of 70 A and an arc voltage of 26 V. An apparatus used for forming the amorphous insulating film 22 (amorphous carbon film) included two filter portions. The filter portions were insulated from each other with a fluorine-containing highly-insulating resin disposed between them. A variable DC voltage source was connected to the filter portions.

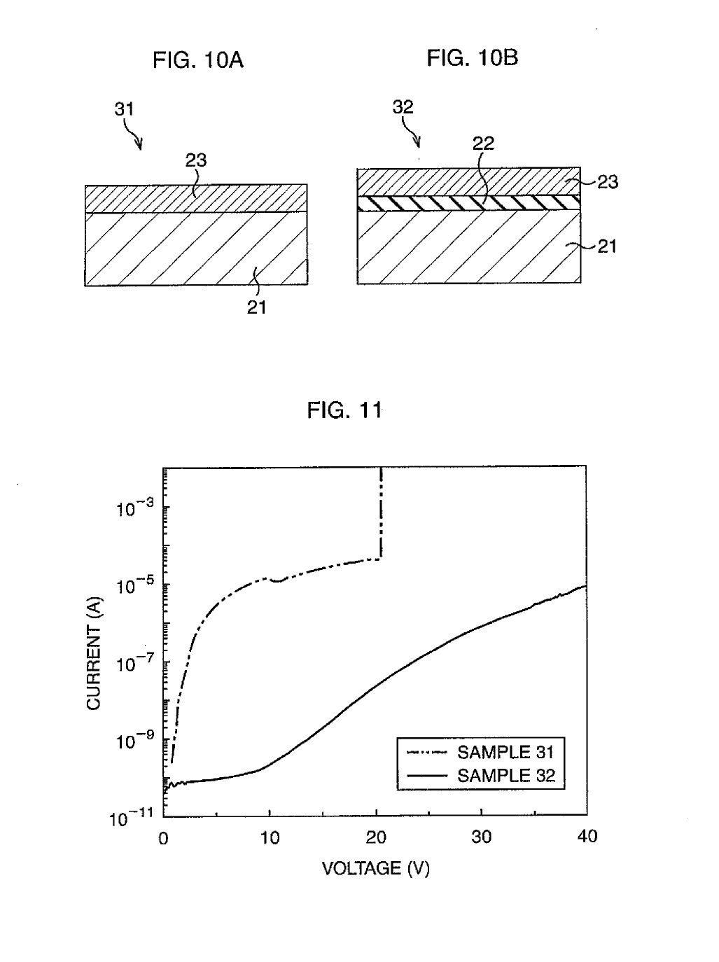

After the samples 31 and 32 were prepared as described above, a gold electrode of 200 nm thick was formed on the surface of the AlN layer 23 of each of the samples 31 and 32. An IV meter was then connected between the back surface of the Si substrate 21 and the gold electrode, and leakage current of the samples 31 and 32 was measured while continuously sweeping the voltage. Results are shown in FIG. 11. The sample 31, representing a prior art, was found to sharply increase in the leakage current immediately after the voltage was applied, and resulted in dielectric breakdown at approximately 20 V. In contrast, the sample 32, representing an embodiment, was found to be very moderate in increase in the leakage current, showing only a low level of leakage current even if the voltage reached 40 V, without dielectric breakdown.

According to the compound semiconductor devices and so forth described above, the breakdown voltage can further be elevated, with the presence of the amorphous insulating film between the substrate and the compound semiconductor stacked structure.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

1-10. (canceled)

11. A power supply apparatus comprising
a compound semiconductor device, which comprises:
a substrate;
a compound semiconductor stacked structure formed over the substrate; and
an amorphous insulating film formed between the substrate and the compound semiconductor stacked structure.

12. An amplifier comprising
a compound semiconductor device, which comprises:
a substrate;
a compound semiconductor stacked structure formed over the substrate; and
an amorphous insulating film formed between the substrate and the compound semiconductor stacked structure.

13. A method of manufacturing a compound semiconductor device, comprising:
forming an amorphous insulating film over a substrate; and
forming a compound semiconductor stacked structure over the amorphous insulating film.

14. The method of manufacturing a compound semiconductor device according to claim 13, wherein the amorphous insulating film is an amorphous carbon film.

15. The method of manufacturing a compound semiconductor device according to claim 13, wherein the amorphous insulating film is formed by a filtered cathodic arc (FCA) process.

16. The method of manufacturing a compound semiconductor device according to claim 13, wherein the forming the compound semiconductor stacked structure comprises forming a buffer layer over the amorphous insulating film.

17. The method of manufacturing a compound semiconductor device according to claim 16, wherein the substrate contains Si, and the buffer layer contains Al.

18. The method of manufacturing a compound semiconductor device according to claim 17, wherein the buffer layer is an AlN layer.

19. The method of manufacturing a compound semiconductor device according to claim 16, wherein the forming the compound semiconductor stacked structure comprises:
forming an electron channel layer over the buffer layer; and
forming an electron supply layer over the electron channel layer.

20. The method of manufacturing a compound semiconductor device according to claim 19, further comprising forming a gate electrode, a source electrode and a drain electrode on or above the electron supply layer.
